(19) United States
(12) Patent Application Publication
(10) Pub. No.: US 2022/0078909 A1
(43) Pub. Date: Mar. 10, 2022

(54) ELECTRONIC COMPONENT MOUNTING SUBSTRATE AND ELECTRONIC DEVICE

(71) Applicant: KYOCERA Corporation, Kyoto-shi, Kyoto (JP)

(72) Inventors: Narutoshi OGAWA, Kirishima-shi (JP); Hikaru KITAHARA, Kirishima-shi (JP); Mitsuhara SAKAI, Kirishima-shi (JP)

(73) Assignee: KYOCERA Corporation, Kyoto-shi, Kyoto (JP)

(21) Appl. No.: 17/417,796

(22) PCT Filed: Dec. 20, 2019
(86) PCT No.: PCT/JP2019/050085

§ 371 Date: Jun. 24, 2021

(30) Foreign Application Priority Data
Dec. 25, 2018 (JP) 2018-240989

(51) Int. Cl. H05K 1/11; H05K 1/03; H01L 23/13

(52) U.S. Cl. CPC H05K 1/115; H01L 23/13; H05K 1/0306

(57) ABSTRACT

An electronic component mounting substrate according to an embodiment of the present disclosure includes a substrate and a plurality of via conductors. The substrate includes a mounting region where an electronic component is to be mounted, and one or more insulating layers. The plurality of via conductors extend through the one or more insulating layers in a thickness direction of the substrate. The plurality of via conductors are arranged, in a plan view of the one or more insulating layers, in m columns in an X direction and n rows in a Y direction, where m and n are natural numbers, and positioned either in odd-numbered rows of odd-numbered columns and even-numbered rows of even-numbered columns only, or in even-numbered rows of odd-numbered columns and odd-numbered rows of even-numbered columns only.

### TECHNICAL FIELD

The present disclosure relates to an electronic component mounting substrate on which an electronic component is to be mounted and an electronic device.

### BACKGROUND ART

There are known electronic component mounting substrates provided with a wiring board including an insulating layer. There are also known electronic devices in which an electronic component is mounted on such an electronic component mounting substrate (refer to Patent Document 1).

### CITATION LIST

### Patent Document

Patent Document 1: JP 2017-157693 A

### SUMMARY

An electronic component mounting substrate according to an embodiment of the present disclosure includes a substrate and a plurality of via conductors. The substrate includes a mounting region where an electronic component is to be mounted and one or more insulating layers. The plurality of via conductors extend through the one or more insulating layers in a thickness direction of the substrate. The plurality of via conductors are arranged, in a plan view of the one or more insulating layers, in m columns in an X direction and n rows in a Y direction, where m and n are natural numbers, and positioned either in odd-numbered rows of odd-numbered columns and even-numbered rows of even-numbered columns only, or in even-numbered rows of odd-numbered columns and odd-numbered rows of even-numbered columns only.

An electronic device according to an embodiment of the present disclosure includes the electronic component mounting substrate and an electronic component mounted on the electronic component mounting substrate.

### BRIEF DESCRIPTION OF DRAWINGS

FIG. 1 is a perspective view of an electronic component mounting substrate according to an embodiment of the present disclosure.

FIG. 2 is a plan view of the electronic component mounting substrate according to the embodiment of the present disclosure.

FIG. 3 is a plan view of the electronic component mounting substrate according to the embodiment of the present disclosure.

FIG. 4 is a plan view of the electronic component mounting substrate according to the embodiment of the present disclosure.

FIG. 5 is a plan view of the electronic component mounting substrate according to the embodiment of the present disclosure.

FIG. 6 is a plan view of the electronic component mounting substrate according to the embodiment of the present disclosure.

FIG. 7 is a cross-sectional view taken along line A-A in FIG. 2 of the electronic component mounting substrate according to the embodiment of the present disclosure.

FIG. 8 is a cross-sectional view taken along line B-B in FIG. 2 of the electronic component mounting substrate according to the embodiment of the present disclosure.

FIG. 9 is a cross-sectional view of an electronic device according to an embodiment of the present disclosure.

FIG. 10 is a cross-sectional view of the electronic device according to the embodiment of the present disclosure.

FIG. 11 is a cross-sectional view of the electronic device according to the embodiment of the present disclosure.

FIG. 12 is a plan view of the electronic component mounting substrate according to the embodiment of the present disclosure.

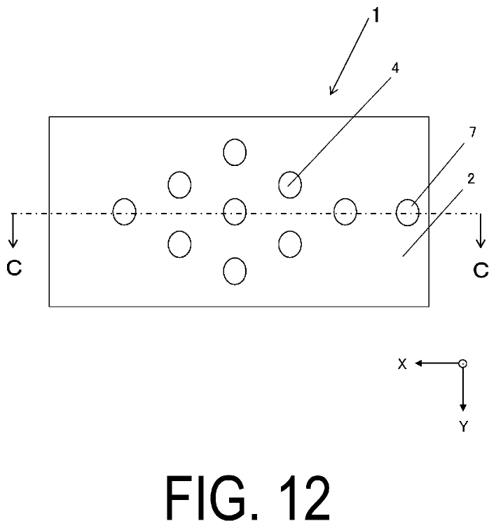

FIG. 13 is a cross-sectional view taken along line C-C in FIG. 12 of the electronic component mounting substrate according to the embodiment of the present disclosure.

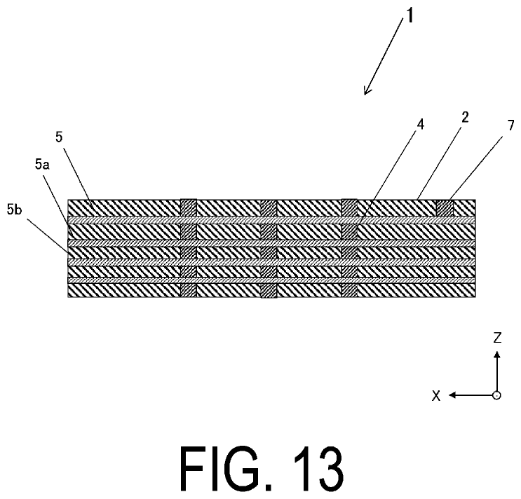

### DESCRIPTION OF EMBODIMENTS

Configuration of Electronic Component Mounting Substrate 1 and Electronic Device 21

Several exemplary embodiments of the present disclosure will be described with reference to the accompanying drawings. Note that the following will describe a configuration in which an electronic component 10 is mounted on an electronic component mounting substrate 1 as an electronic device 21. With respect to the electronic component mounting substrate 1 and the electronic device 21, any direction may be defined as upward or downward, but for the sake of simplicity, a Cartesian coordinate system XYZ will be used herein, with a positive side in the Z direction defined as upward. Further, the electronic component 10 may be a capacitor, an optical semiconductor device such as a laser diode (LD) or a photo diode (PD), or an imaging element such as a charge coupled device (CCD) or a complementary metal oxide semiconductor (CMOS), for example. Further, the electronic component 10 may be a light emitting element such as a light emitting diode (LED), an integrated circuit such as a large scale integration (LSI), or the like.

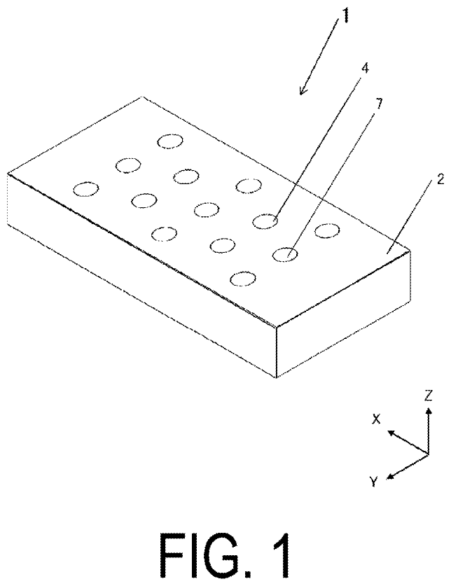

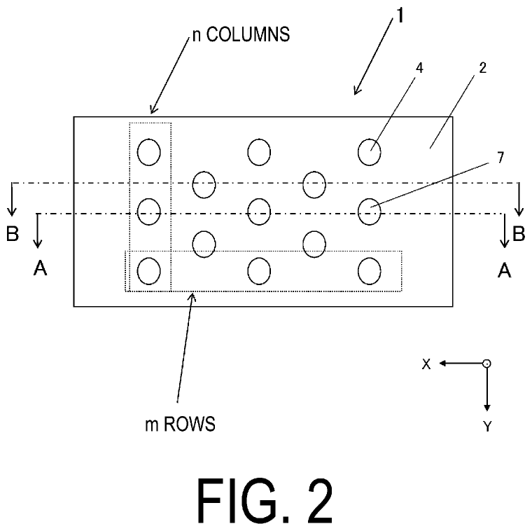

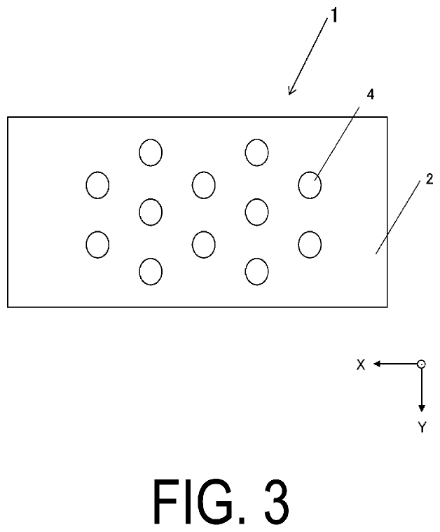

The electronic component mounting substrate 1 includes a substrate 2. The substrate 2 may include a flat plate portion and a frame portion positioned on the flat plate portion, or may include only a frame portion or only a flat plate portion. Note that, in the examples illustrated in FIG. 1 to FIG. 3, the electronic component mounting substrate 1 includes a frame portion and a flat plate portion.

As a material of an insulating layer 5 forming the frame portion and the flat plate portion, an electrically insulating ceramics or a resin (plastic or thermoplastic resin, for example), for example, is used. Note that, in the present specification, the substrate 2 refers to an insulating substrate including the frame portion, the flat plate portion, or both the frame portion and the flat plate portion. The substrate 2 includes one or more insulating layers 5.

Examples of the electrically insulating ceramics used as the material of the insulating layer 5 forming the frame portion and the flat plate portion include an aluminum oxide-based sintered body, a mullite-based sintered body, a silicon carbide-based sintered body, an aluminum nitride-based sintered body, a silicon nitride-based sintered body, and a glass ceramic-based sintered body. As the resin used as the material of the insulating layer 5 forming the frame portion and the flat plate portion, a thermoplastic resin, an epoxy resin, a polyimide resin, an acrylic resin, a phenol resin, or a fluorine-based resin, for example, may be used. As the fluorine-based resin, a polyester resin or an ethylene tetrafluoride resin, for example, may be used.

As described above, the substrate 2 may be formed of only the frame portion or only the flat plate portion, or may be formed by layering the flat plate portion on an upper surface of the frame portion or a lower surface of the frame portion or on the upper surface of the frame portion and the lower surface of the frame portion.

As illustrated in FIG. 1 to FIG. 3, the substrate 2 including the frame portion and the flat plate portion may be formed of six insulating layers 5 or may be formed of five or fewer or seven or more insulating layers 5. When the number of insulating layers 5 is five or less, the electronic component mounting substrate 1 can be made thinner. Further, when the number of insulating layers 5 is six or more, the rigidity of the electronic component mounting substrate 1 can be increased.

The size of one side of an outermost periphery of the substrate 2 may be, for example, from 0.3 mm to 10 cm. When the substrate 2 has a quadrangular shape in a plan view, the substrate 2 may have a square shape or a rectangular shape. Further, a thickness of the substrate 2 may be 0.2 mm or greater.

The frame portion and the flat plate portion may be formed of the same material or may be formed of different materials. When the frame portion and the flat plate portion are formed of the same material, the frame portion and the flat plate portion can be fired at the same temperature. Further, the frame portion and the flat plate thus obtained have similar basic physical properties such as coefficients of thermal expansion and therefore, when the electronic component 10 generates heat after being mounted, cracks and the like caused by a difference in thermal expansion are less likely to occur. Further, when the frame portion and the flat plate portion are formed of different materials, the materials can be selected in accordance with the situation.

An electrode pad 3 may be positioned on the frame portion, an upper surface of the flat plate portion, or a lower surface of the flat plate portion. Further, an internal wiring line 6 formed between the insulating layers 5 and a plurality of via conductors 4 that vertically connect the internal wiring lines 6 or that vertically connect the electrode pad 3 and the internal wiring line 6 or the like are positioned on the upper surface or the lower surface of the flat plate portion. With regard to the internal wiring line 6 or the via conductors 4, a portion of the internal wiring line 6 or the via conductors 4 may be exposed on the surface of the substrate 2. The via conductors 4 extend through the insulating layer 5 in the thickness direction of the substrate 2.

When the insulating layer 5 includes an electrically insulating ceramics, the electrode pad 3, the internal wiring line 6, and the via conductors 4 may include tungsten (W), molybdenum (Mo), manganese (Mn), silver (Ag), or copper (Cu). Further, when the insulating layer 5 includes an electrically insulating ceramics, the electrode pad 3, the internal wiring line 6, and the via conductors 4 may include an alloy containing at least one type of metal material from among tungsten (W), molybdenum (Mo), manganese (Mn), silver (Ag), and copper (Cu), or the like.

When the insulating layer 5 includes a resin, the electrode pad 3, the internal wiring line 6, and the via conductors 4 may include copper (Cu), gold (Au), aluminum (Al), nickel (Ni), molybdenum (Mo), or titanium (Ti). Further, when the insulating layer 5 includes a resin, the electrode pad 3, the internal wiring line 6, and the via conductors 4 may include an alloy containing at least one type of metal material from among copper (Cu), gold (Au), aluminum (Al), nickel (Ni), molybdenum (Mo), and titanium (Ti), or the like.

The plurality of via conductors 4 are arranged in m columns in the X direction and n rows in the Y direction, where m and n are natural numbers. The via conductors 4, in a plan view, are positioned either in odd-numbered rows of odd-numbered columns and even-numbered rows of even-numbered columns only, or in even-numbered rows of odd-numbered columns and odd-numbered rows of even-numbered columns only. The arrangement of the via conductors 4 described herein corresponds to a lattice-like grid. Here, the natural number is a general natural number in mathematics and is a positive integer. The via conductors 4 positioned in a lattice shape allow an electric resistance to be uniform in the electronic component mounting substrate 1. Further, when a gap between the columns and a gap between the rows in which the plurality of via conductors 4 are disposed are the same, m and n may be the same natural number. When the gap between the columns and the gap between the rows in which the plurality of via conductors 4 are disposed are the same and m and n are the same natural number, the electric resistance can be even more uniform in the electronic component mounting substrate 1.

The electronic component mounting substrate 1 according to the embodiment of the present disclosure has the configuration described above, making it possible to maintain the electric resistance value of the electronic component mounting substrate 1 low and maintain the flatness of the electronic component mounting substrate 1.

Note that, in the case of an electronic component mounting substrate in which via conductors are densely packed, even if the electric resistance value can be lowered, the flatness of the substrate may be impaired due to thermal deformation or the like. In contrast, in the electronic component mounting substrate 1 of the present disclosure, due to the arrangement of the via conductors 4 described above, the electric resistance value of the electronic component mounting substrate 1 can be lowered and the flatness of the electronic component mounting substrate 1 can be maintained.

The substrate 2, in a plan view, may include an electric power feeding point 7 at an end portion of the substrate 2. When the substrate 2 includes the electric power feeding point 7, the plurality of via conductors 4 may be greater in number in a second column than in a first column near the electric power feeding point 7. When the number of via conductors 4 in the second column is greater than the number of via conductors 4 in the first column near the electric power feeding point 7, the electric resistance value of the electronic component mounting substrate 1 can be lowered without providing unnecessary via conductors 4.

The substrate 2 may include a first insulating layer 5a and a second insulating layer 5b. The first insulating layer 5a and the second insulating layer 5b may include the plurality of via conductors 4 and, in a plane perspective, the plurality of via conductors 4 of the first insulating layer 5a and the plurality of via conductors 4 of the second insulating layer 5b may be positioned at least partially overlapping each other. When the plurality of via conductors 4 of the first insulating layer 5a and the plurality of via conductors 4 of the second insulating layer 5b are positioned at least partially overlapping each other, the steps for fabricating the plurality of via conductors 4 of the first insulating layer 5a and the plurality of via conductors 4 of the second insulating layer 5b can be simplified. Note that a plane perspective in the present disclosure refers to viewing through the object in a negative direction opposite the Z direction illustrated in FIG. 1.

Further, the first insulating layer 5a and the second insulating layer 5b may include the plurality of via conductors 4 and, in a plane perspective, the plurality of via conductors 4 of the first insulating layer 5a and the plurality of via conductors 4 of the second insulating layer 5b may be positioned apart from each other. In other words, in a plane perspective, the plurality of via conductors 4 of the first insulating layer 5a and the plurality of via conductors 4 of the second insulating layer 5b need not be positioned overlapping each other. When the plurality of via conductors 4 of the first insulating layer 5a and the plurality of via conductors 4 of the second insulating layer 5b are positioned apart from each other, the number of via conductors 4 can be reduced in each of the insulating layers 5, and the electric resistance value of the entire electronic component mounting substrate 1 can be lowered.

In a plan view of the substrate 2, among the plurality of via conductors 4, three via conductors 4 adjacent to each other may be positioned in an equilateral triangle. When the three via conductors 4 adjacent to each other are positioned in an equilateral triangle in a plan view, the electronic component mounting substrate 1 can have a uniform electric resistance value.

A plating layer may be provided on the exposed surfaces of the electrode pad 3, the internal wiring line 6, and the via conductors 4. Oxidation of the exposed surfaces of the electrode pad 3 for external circuit connection, the internal wiring line 6, and the via conductors 4 can be reduced by the plating layer.

### Configuration of Electronic Device 21

An example of the electronic device 21 is illustrated in FIG. 1 to FIG. 3. The electronic device 21 includes the electronic component mounting substrate 1 and the electronic component 10 mounted on the electronic component mounting substrate 1.

The electronic device 21 includes the electronic component mounting substrate 1 and the electronic component 10 mounted on the electronic component mounting substrate 1. The electronic component 10 may be an imaging element such as a complementary metal oxide semiconductor (CMOS) or a charge coupled device (CCD), for example. Alternatively, the electronic component 10 may be a light emitting element such as a light emitting diode (LED), an integrated circuit such as a large scale integrated (LSI), or the like. Note that the electronic component 10 may be disposed on an upper surface of the substrate 2 with an adhesive interposed therebetween. When the electronic component 10 is disposed on the upper surface of the substrate 2 with an adhesive interposed therebetween, the upper surface of the substrate 2 functions as a mounting region of the electronic component 10. Examples of the adhesive that can be used include silver epoxy or a thermosetting resin.

The electronic device 21 may include a lid 12. The lid 12 may cover the electronic component 10 and be bonded to an upper surface of the electronic component mounting substrate 1. Here, the electronic component mounting substrate 1 may be connected to the lid 12 on the upper surface of the frame portion, or may be provided with a frame-like body that supports the lid 12 and surrounds the electronic component 10 on the upper surface of the substrate 2. Further, the frame-like body and the substrate 2 may be made from the same material or may be made from different materials.

When the frame-like body and the substrate 2 are made from the same material, the substrate 2 and the frame-like body may be integrated with each other by providing the uppermost insulating layer 5 with an opening, or the substrate 2 and the frame-like body may be bonded by a brazing material or the like.

Further, as an example in which the substrate 2 and the frame-like body are made from different materials, the frame-like body may be made from the same material as a lid bonding material 14 that bonds the lid 12 and the substrate 2 to each other. At this time, the lid bonding material 14 provided thickly allows the lid 12 and the substrate 2 to adhere to each other and can support the lid 12. Examples of the lid bonding material 14 include a thermosetting resin, a low-melting point glass, or a brazing material including a metal component. Further, when the frame-like body and the lid 12 are made from the same material, the frame-like body and the lid 12 may be formed as one unit.

When the electronic component 10 is an imaging element such as a CMOS or a CCD, or a light emitting element such as an LED, for example, a material having high transparency such as a glass material may be used for the lid 12. Further, when the electronic component 10 is an integrated circuit or the like, for example, a metal material or an organic material may be used for the lid 12.

The lid 12 is bonded to the electronic component mounting substrate 1 via the lid bonding material 14. As the material constituting the lid bonding material 14, a thermosetting resin, a low-melting point glass, or a brazing material including a metal component may be used, for example.

### Manufacturing Method for Electronic Component Mounting Substrate 1 and Electronic Device 21

Next, an example of a manufacturing method for the electronic component mounting substrate 1 and the electronic device 21 according to an embodiment of the present disclosure will be described. Note that the example of the manufacturing method for the electronic component mounting substrate 1 and the electronic device 21 of the embodiment of the present disclosure described below is a manufacturing method for the substrate 2 that uses a multipiece wiring board.

(1) First, a ceramic green sheet that will constitute the substrate 2 is formed. For example, in the case of obtaining the substrate 2 that is mainly an aluminum oxide (Al₂O₃)-based sintered compact, a powder such as silica (SiO₂), magnesia (MgO), or calcia (CaO) is added as a sintering aid to the Al₂O₃ powder. Then, a mixture obtained by further adding a suitable binder, solvent, and plasticizer to the Al₂O₃ powder is kneaded to form a slurry. A multipiece ceramic green sheet can be obtained by applying a molding method such as a doctor blade method, a calender roll method, or the like to the slurry mixture.

Note that, when the substrate 2 mainly includes a resin, for example, the substrate 2 can be formed by molding the resin prior to curing through a method such as a transfer mold method or an injection mold method using a metal mold that enables the resin to be molded into a predetermined shape. Further, the substrate 2 may be formed by impregnating a base member containing glass fibers with a resin, such as a glass epoxy resin, for example. In this case, the substrate 2 can be formed by impregnating a base member containing glass fibers with an epoxy resin precursor and thermally curing this epoxy resin precursor at a predetermined temperature.

(2) Next, using a screen printing method or the like, a metal paste is applied to or caused to fill a portion of the ceramic green sheet obtained in the step (1) that will become the electrode pad 3, the electrode pad for external circuit connection, the internal wiring line 6, and the via conductors 4. This metal paste is fabricated so as to have an appropriate viscosity by adding a suitable solvent and binder to the metal powder containing the metal materials described above, and kneading the resultant. Note that a glass or ceramics may also be included in the metal paste in order to increase the bonding strength with the substrate 2.

Further, when the substrate 2 includes a resin, the electrode pad 3, the electrode pad for external circuit connection, the internal wiring line 6, and the via conductors 4 can be fabricated by a sputtering method, a vapor deposition method, or the like.

(3) Next, the aforementioned green sheet is processed using a metal mold or the like. Here, a recessed portion may be provided in a predetermined location on the green sheet that will become the substrate 2 using a metal mold, punching, laser, or the like.

(4) Next, the ceramic green sheets that will become the respective insulating layers 5 are layered and pressed. The ceramic green sheet layered body that will become the substrate 2 (the electronic component mounting substrate 1) may be fabricated by the steps (1) to (4) described above. Further, a recessed portion may be provided at a predetermined position in the ceramic green sheet layered body. Further, the recessed portion may be provided by layering a plurality of ceramic green sheets, and a metal mold, punching, laser, or the like may be used on the ceramic green sheets to create a through hole at the position corresponding to the recessed portion after firing.

(5) Next, the ceramic green sheet layered body is fired at a temperature from approximately 1500° C. to approximately 1800° C. to obtain a multipiece wiring board on which a plurality of the substrates 2 (electronic component mounting substrates 1) are arrayed. Note that, in step (5), the metal paste described above is fired at the same time as the ceramic green sheets forming the substrates 2 (electronic component mounting substrate 1), and forms the electrode pad 3, the internal wiring line 6, and the via conductors 4.

(6) Next, a surface treatment such as plating is performed on a surface of the multipiece wiring board in which the plurality of substrates 2 (electronic component mounting substrates 1) are arrayed.

(7) Next, the plurality of substrates 2 (electronic component mounting substrates 1) are obtained by dividing the multipiece wiring board obtained by firing. In this division, a method in which split grooves are formed in the multipiece wiring board in locations that will serve as the outer edges of the substrates 2 (electronic component mounting substrates 1), and the multipiece wiring board is then broken along those split grooves can be used. Alternatively, a method in which the multipiece wiring board is cut, by slicing or the like, along the locations that will serve as the outer edges of the substrates 2 (electronic component mounting substrates 1) or the like can be used. Note that the split grooves can be formed by using a slicing device to form cuts having a depth less than the thickness of the multi-piece wiring substrate after firing. Alternatively, the split grooves can be formed by pressing a cutter blade against the ceramic green sheet layered body used as the multipiece wiring board, or by using a slicing device to form cuts having a depth less than the thickness of the ceramic green sheet layered body. Note that, before the multipiece wiring board described above is divided into a plurality of substrates 2 (electronic component mounting substrates 1), the electrode pad 3, the electrode pad for external circuit connection, and the exposed wiring conductors may be plated using electrolysis. Alternatively, the electrode pad 3, the electrode pad for external circuit connection, and the exposed wiring conductors may be plated using an electric field after the multipiece wiring substrate has been divided into the plurality of substrates 2 (electronic component mounting substrates 1).

When the substrate 2 is formed of a resin, the substrate 2 can be divided using, for example, a slicing method or a laser cutting method.

(8) Next, the electronic component 10 is mounted on the upper surface or the lower surface of the electronic component mounting substrate 1. Note that, among the surfaces of the electronic component mounting substrate 1, a region on which the electronic component 10 is mounted is referred to as a mounting region. The electronic component 10 is electrically bonded to the electronic component mounting substrate 1 by an electronic component connecting material 13 for wire bonding or the like. Further, at this time, the electronic component 10 may be fixed to the electronic component mounting substrate 1 by providing an adhesive or the like on the electronic component 10 or the electronic component mounting substrate 1. Further, the electronic component mounting substrate 1 and the lid 12 may be bonded using the lid bonding material 14 after the electronic component 10 has been mounted in the mounting region of the electronic component mounting substrate 1.

The electronic device 21 can be fabricated by fabricating the electronic component mounting substrate 1 and mounting the electronic component 10 in the mounting region of the electronic component mounting substrate 1 as in the steps (1) to (8) described above. Note that an order of the above-described steps (1) to (8), the number of steps, and the like are not specified. Further, it is not necessary to go through all of the steps (1) to (8) described above.

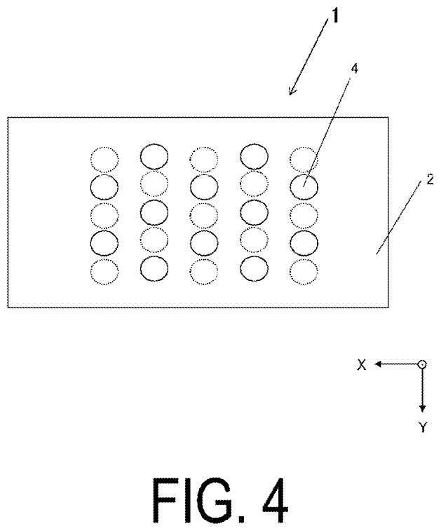

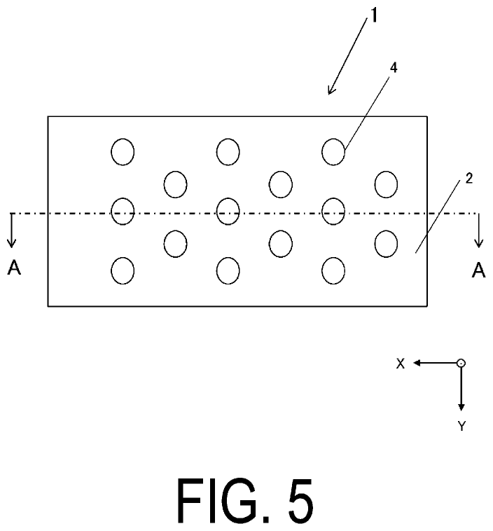

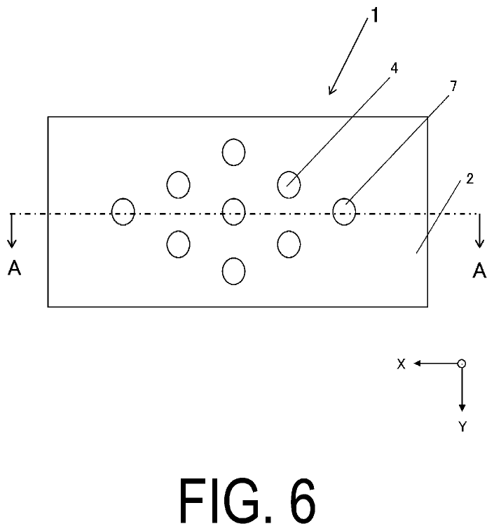

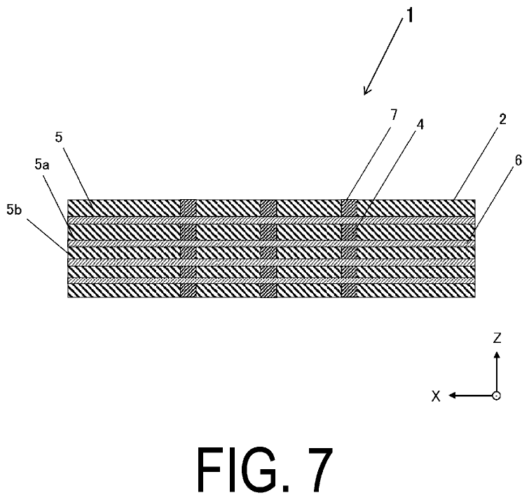

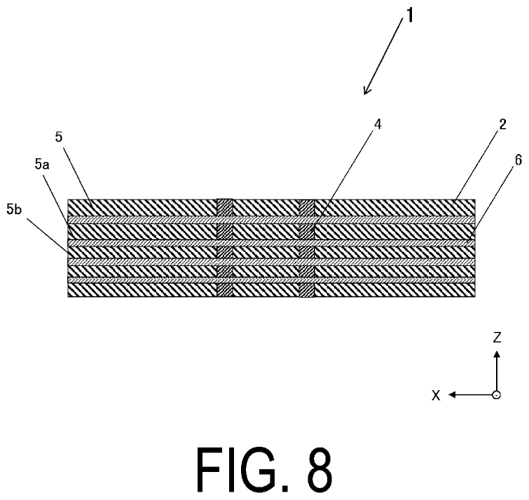

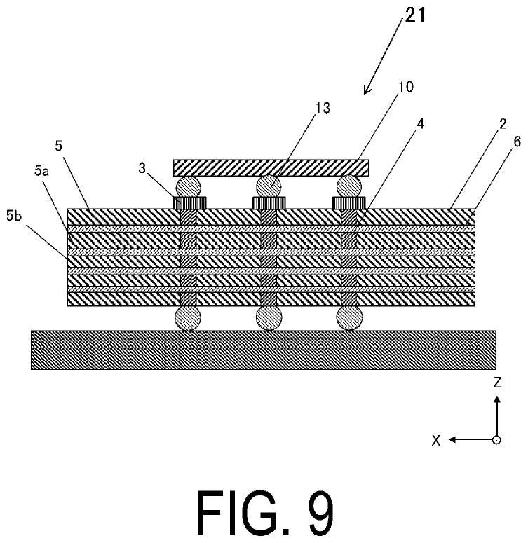

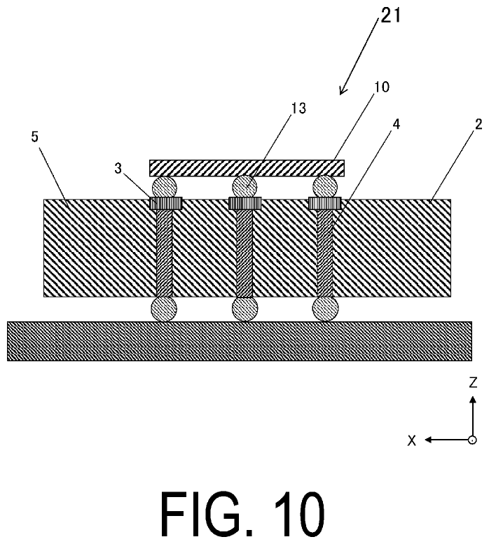

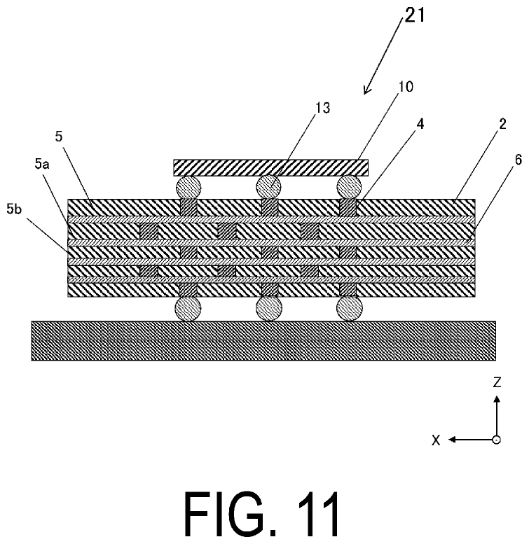

Note that the present disclosure is not limited to the examples in the embodiments described above. Further, various modifications are possible in each configuration, such as numerical values. Further, for example, in the examples illustrated in FIG. 1 to FIG. 11, the shape of the electrode pad 3 is a quadrangular shape in a cross-sectional view, but may be a circular shape or another polygonal shape. Further, the arrangement, number, and shape of the electrode pad 3, the mounting method for the electronic component 10, and the like in the embodiments of the present disclosure are not specified. Note that various combinations of the embodiments of the present disclosure are not limited to the examples in the above-described embodiments.

### REFERENCE SIGNS LIST

1 Electronic component mounting substrate
2 Substrate
3 Electrode pad
4 Via conductor
5 Insulating layer
5a First insulating layer
5b Second insulating layer
6 Internal wiring line
7 Electric power feeding point
10 Electronic component
12 Lid
13 Electronic component bonding material
21 Electronic device

1. An electronic component mounting substrate comprising:
a substrate comprising a mounting region where an electronic component is to be mounted and one or more insulating layers; and
a plurality of via conductors extending through the one or more insulating layers in a thickness direction of the substrate,
wherein the plurality of via conductors are arranged, in a plan view of the one or more insulating layers, in m columns in an X direction and n rows in a Y direction, where m and n are natural numbers, and positioned either in odd-numbered rows of odd-numbered columns and even-numbered rows of even-numbered columns only, or in even-numbered rows of odd-numbered columns and odd-numbered rows of even-numbered columns only.

2. The electronic component mounting substrate according to claim 1, wherein
m and n are the same natural number.

3. The electronic component mounting substrate according to claim 1, wherein
the substrate comprises an electric power feeding point at an end portion in a plan view, and
the plurality of via conductors are greater in number in a second column than in a first column near the electric power feeding point.

4. The electronic component mounting substrate according to claim 1, wherein
the substrate comprises a first insulating layer and a second insulating layer, and
the first insulating layer and the second insulating layer each comprise the plurality of via conductors and, in a plane perspective, the plurality of via conductors of the first insulating layer and the plurality of via conductors of the second insulating layer are positioned at least partially overlapping each other.

5. The electronic component mounting substrate according to claim 1, wherein
the substrate comprises a first insulating layer and a second insulating layer below the first insulating layer, and
the first insulating layer and the second insulating layer each comprise the plurality of the via conductors and, in a plane perspective, the plurality of via conductors of the first insulating layer and the plurality of via conductors of the second insulating layer are positioned apart from each other.

6. The electronic component mounting substrate according to claim 1, wherein
in a plan view, among the plurality of via conductors, three via conductors adjacent to each other are positioned in an equilateral triangle.

7. An electronic device comprising:
the electronic component mounting substrate according to claim 1; and
an electronic component mounted in the mounting region.

8. The electronic component mounting substrate according to claim 5, wherein
in the plan perspective view, the plurality of via conductors of the second insulating layer are arranged in at least one of the same column and the same row which the plurality of via conductors of the first insulating layer are arranged.

9. The electronic component mounting substrate according to claim 5, wherein
the substrate further comprises a third insulating layer below the second insulating layer and a fourth insulating layer below the third insulating layer,
the third insulating layer and the fourth insulating layer each comprise the plurality of the via conductors and,
in a cross-sectional view, the plurality of via conductors of the first insulating layer and the plurality of via conductors of the third insulating layer are positioned at least partially overlapping each other, and
in a cross-sectional view, the plurality of via conductors of the second insulating layer and the plurality of via conductors of the fourth insulating layer are positioned at least partially overlapping each other.

10. The electronic component mounting substrate according to claim 4, further comprising an internal wiring line located between the first insulating layer and the second insulating layer and electrically connected to the plurality of via conductors.

11. The electronic component mounting substrate according to claim 10, wherein
the internal wiring line electrically connects a pair of via conductors among the plurality of via conductors positioned adjacent each other.

12. The electronic component mounting substrate according to claim 1, wherein
in a plan view, at least one of the plurality of via conductors is positioned overlapping a centor of the substrate.

13. The electronic component mounting substrate according to claim 9, wherein
in a cross-sectional view, the plurality of via conductors of the second insulating layer and the plurality of via conductors of the fourth insulating layer are positioned outside of the plurality of via conductors of the first insulating layer and the plurality of via conductors of the third insulating layer.

14. The electronic component mounting substrate according to claim 9, wherein
in a cross-sectional view, the plurality of via conductors of the first insulating layer and the plurality of via conductors of the third insulating layer are positioned outside of the plurality of via conductors of the second insulating layer and the plurality of via conductors of the fourth insulating layer.
